(19) United States
(12) Patent Application Publication
(10) Pub. No.: US 2008/0205017 A1
(43) Pub. Date: Aug. 28, 2008

(54) Interconnection and Packaging Method for Biomedical Devices with Electronic and Fluid Functions

(75) Inventors: Ton Nellissen, Horst (NL); Reinhold Wimberger-Friedl, Veldhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/996,515

(22) PCT Filed: Jul. 12, 2006
(86) PCT No.: PCT/IB2006/052367

§ 371 Date: Jan. 23, 2008

Related U.S. Application Data
(60) Provisional application No. 60/702,215, filed on Jul. 25, 2005.

(51) Int. Cl. H05K 7/14

(52) U.S. Cl. 361/796

(57) ABSTRACT

An interconnection and packaging method is provided for manufacturing of Lab-on-chip (LOC) and Micro Total Analyses Systems. Different functions, such as biosensors, heaters, coolers, valves, and pumps, are combined in an electronic/mechanical/fluidic module by flip-chip technology using an ultrasound bounding process. A predefined polymeric ring on the chip serves as a seal.

The present invention relates to electronic systems in the area of medical diagnostics, and particularly to an integrated interconnection and packaging system for connecting various functions in a combined electronic, mechanical, and fluidic module.

New developments in the field of medical diagnostics are Lab-on-chip (LOC) and μ Total Analyses Systems (μTAS). These electronic systems are used for detection and analyses of specific biomolecules, such as DNA and proteins. These types of micro-systems contain fluidic, electrical, and mechanical functions, such as micro pumps, valves, mixers, filters, heaters, coolers, biosensors, etc., and must be connected and packaged in a reliable and cost-effective way to protect delicate components from the environment.

Integration and packaging can be a challenging task. For example, integrated microfluidic sensors need to combine various functions on a single template, and other functions on separate functional substrates, i.e., silicon, which need to be assembled with the microfluidic channel system. With small channel geometries, integration of interfaces between the substrates and the channel plate is difficult as they need to be tight, accurate, and reproducible, while maintaining packaging cost low by minimizing a footprint. Further, in the electronic components, which need an electric interface, a separation of the wet interface is critical. Moreover, bonding techniques must be compatible with the biochemical reagents and surface treatments present on the functional substrates. Since the footprint of the functional substrates is much smaller than that of the microfluidic channel system and the application technologies of the functional layers and materials are not compatible with the microfluidic channel plate assembly requirements, it is difficult to assemble closed channel systems containing biological functionality and electric interfaces.

The shortcomings of the prior art noted above are addressed by the inventive packaging system operable to house various integrated circuits integrated into a combined electronic/mechanical/fluidic module.

The present invention provides a generic interconnection and packaging solution to connect different functions in a combined electronic/mechanical/fluidic module. One aspect of the invention is that the functional elements, such as sensors and actuators, are attached to a preassembled fluidic and electric interconnect system in the final step.

According to another aspect of the invention, the module includes a fluidic part and a plate containing the electrical interconnection circuitry. The plate with the interconnection circuitry is precisely aligned and then bonded or laminated to the fluidic part. In this way, a base module is obtained with electrical and fluidic infrastructure. The required functions, such as biosensors, heaters, valves, pumps, etc., are attached to the module by flip-chip technology using ultrasonic bonding or laser welding. A predefined polymeric ring on the chip acts as a seal. During bonding of the chip, the seal ring on the chip comes in intimate contact with the substrate and thereby seals the fluidic channels from the external conditions.

Still another aspect is that the present invention may be realized in a simple, reliable, and inexpensive implementation.

Yet another aspect is that the present invention may be applicable in biomedical applications such as μTAS and LOC, molecular diagnostics, food and environmental sensors. In addition to the analyses of bio-molecules, the present invention may also be applied in the synthesis of chemical or biological compounds.

Details of the invention disclosed herein shall be described with the aid of the figures listed below, wherein:

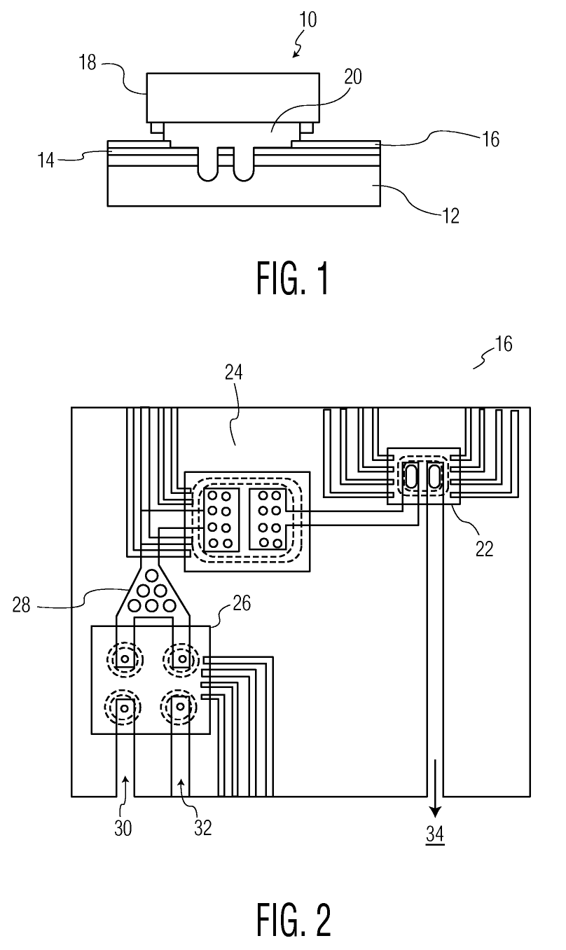

FIG. 1 depicts an apparatus, including fluid and electrical systems, according to the present invention;

FIG. 2 is a schematic view of various functions integrated on a single module according to the present invention;

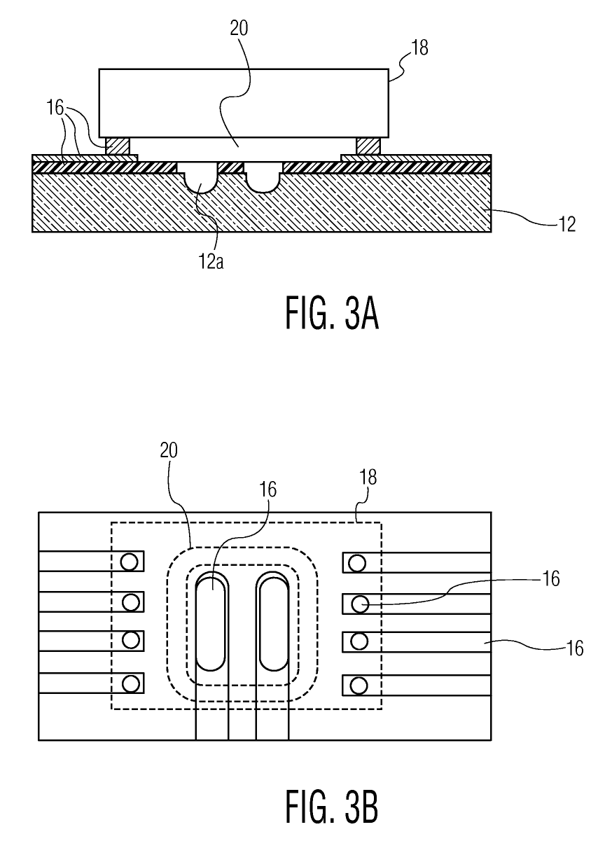

FIG. 3a illustrates the manufacturing steps of integrating various functions on a single module according to the present invention;

FIG. 3b is another view showing the manufacturing steps according to the present invention;

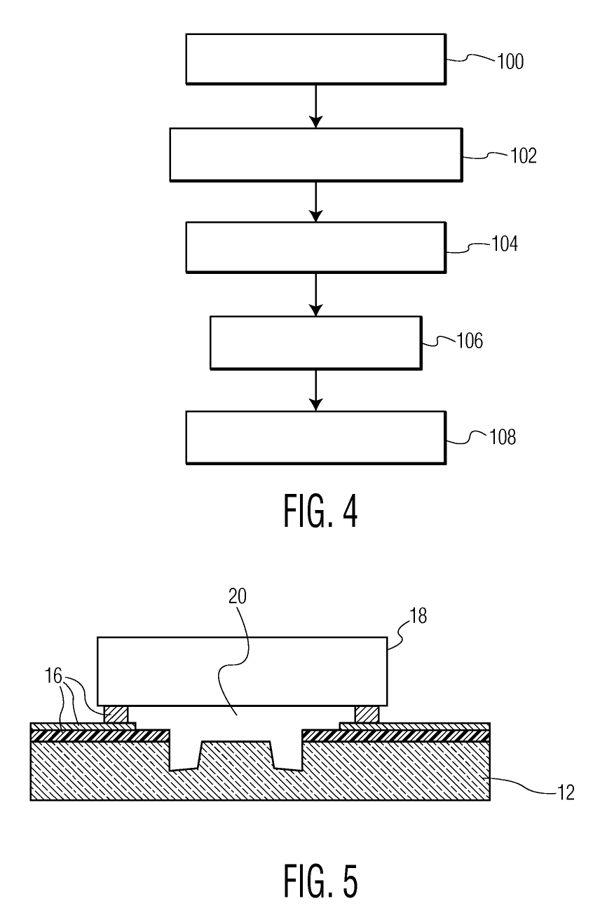

FIG. 4 is a flowchart of a process of integrating various functions on a single module according to the present invention;

FIG. 5 shows an alternate embodiment according to another embodiment of the present invention; and

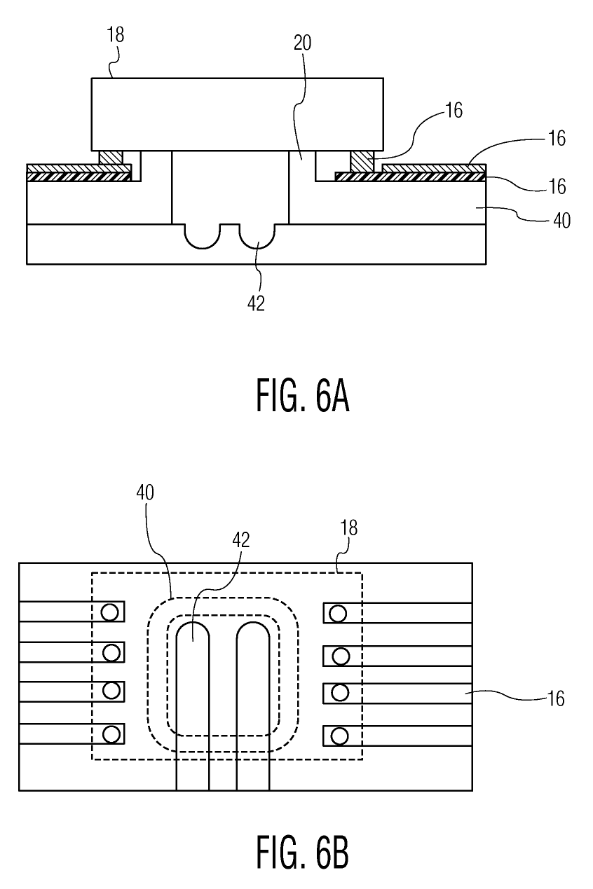

FIG. 6 shows integrated circuits on a single module according to another embodiment of the present invention.

Referring now in specific detail to the drawings in which like reference numerals identify similar or identical elements throughout the several views, and initially to FIG. 1, an overview is shown of an exemplary architecture for an electronic apparatus 100 according to the present invention.

Referring to FIG. 1a, a representative component of the inventive apparatus 10 includes a fluidic part 12 and a plate 14 containing an electrical interconnection circuitry 16. The plate 14 and the interconnection circuitry 16 is precisely aligned and then bonded or laminated to the fluidic part 12. Various functions, for example, a biosensor 18 may be coupled to the module using a flip-chip technology using low temperature ultrasonic bonding or a laser welding technique. A predefined polymeric ring 20, serving as a seal from the environment, is provided between a layer comprising the plate and interconnection circuitry 16, and functions 18 to make a close contact.

FIG. 2 shows a schematic view of various electronic circuits integrated into a single module according to the present invention. Different circuits that may be integrated into the electrical interconnection circuitry 16 may include biosensor chip 22, heater chip 24, dual valve chip 28, mixing chamber 28, sample inlet 30, reagent inlet 32, and a waste outlet 34. It should be understood that although a number of different circuits shown in FIG. 2 is small for the purpose of illustration, in practice, the present invention may include a much larger number of other circuitries.

Referring to FIGS. 3a and 3b, a detailed description of the manufacturing steps of integrating various electronic elements on a single module is explained further. The manufacturing step will be explained with reference to biosensor chip 18, but the construction of other electronic elements on the single module is essentially the same as that described above with respect to FIGS. 3a and 3b. Hence, the discussion of other components described in the preceding paragraphs is omitted to avoid redundancy.

Referring to FIG. 3a, the fluidic part 12 may be a silicon wafer or a glass plate with channels and cavities 12a obtained by photolithography and/or wet or dry etching. It can also be a polymeric part made by injection molding (PMMA, COP) or casting (PDMS). In case of molding or casting, the required precise inserts (masters) are obtained via Lithography and plating (LIGA), micromaching and/or etching.

The sheet containing the interconnection circuitry 16 may be glass, flexfoil, or PCB material and provided by sputtering, lithography, and a plating process, and is preferably a combination of Cr/Cu/Ni/Au layers. Through-holes in the sheet are obtained by lithography and etching, laser ablation, mechanical punching (Flexfoil, PCB), or etching (glass). The sheet containing the interconnection circuitry 16 is precisely aligned with respect to the fluidic part 12 and then bonded at elevated temperatures (glass-to-glass, polymer-to-polymer) or glued (polymer-to-glass) using an adhesive. Here, a thin adhesive layer is preferably applied to the fluidic part 12 by roller coating or tampon printing, so that the recessed areas (channels and cavities 12a) stay free from the adhesive. Alternatively, a photo-definable adhesive layer or pressure-sensitive adhesive (PSA) may be used.

Referring to FIG. 4, the process of integrating various circuitries on a single module is shown according to the present invention. First, in step 100, a wafer is provided. Different integrated circuits, such as biosensors, valves, and heater elements, are manufactured on SI or glass wafers using IC and MEMS process technologies. Note that integrated circuits, i.e., electronic components, fabricated in an array on a wafer is well know to those skill in the art. On a wafer level, in step 102, a polymeric seal ring slightly thicker than the Au bumps is provided. A commercially available seal ring, such as photo-definable silicone WL5150 of Dow Corning or SU-8 polymer of MRT may be used. The back-side surface of a wafer is attached to a tape, such as Nitto blue tape Next each wafer, in step 104, is separated into an individual chip by dicing Then the wafers are thoroughly rinsed with de-ionized water to remove any residues or contamination from sawing and then dried. Now it is possible in this stage of the process to provide a biosensor chip with the necessary immobilized bio-molecule probes (spotting), e.g., by advanced inkjet printing technology in step 106. The fact that the chips are still closely together in wafer format facilitates the spotting operation. After spotting with probe molecules, or the absence of such spotting, the individual chips are removed form the blue tape using a dedicated tool. Thereafter, the chips are attached directly onto a base module by ultrasonic bonding in step 108. The base plate having fluid channels is provided to form a base module step 70, and a cover plate having interconnection circuitry and holes is provided in step 80, then the base plate and the cover plate is coupled together in step 90. Ultrasonic boding in step 108 is preformed at room temperature, which prevents destruction of bio-molecules. The soft ring on the chip seals the biosensor surface from the outside world. Instead of ultrasonic bonding, laser soldering may be used. It is also possible to use a thermal or UV curable adhesive to attach the chip. In this case the seal ring is dipped in a thin layer (1-5 micron) of glue before placement. After chip bonding a polymer underfill can be applied to increase the adhesion strength and sealing in step 110.

In an alternate embodiment, the sealing ring from the silicon substrate may be omitted and instead use a printing technique or an integration technique in a molded channel plate. This alternate means provides more freedom in the material choice and is more economical than performing lithography on the wafer.

Further, the height of the seal ring determines the channel height at the position of the sensor. Hence, this height must be easy to vary and independent of the bump height after the bonding process. To achieve this, the flex between the channels 12a can be removed and also adjust the height and geometry of the fluidic plate, as shown in FIG. 5.

Referring to FIG. 6, the provision of integrated circuits on a single module according to another embodiment will be explained. The construction and operation of this embodiment are essentially the same as that described above with respect to FIG. 1, except that the seal ring may be integrated in an extra flexible intermediate layer 40, such as PMDS. This layer serves to determine the dimensions of the channels or cavity 42. The layer can be attached to a rigid plastic plate 42 (e.g., PMMA) containing the channels, as shown in FIG. 6. The discussion of similar components described in the preceding paragraphs is omitted to avoid redundancy, as they are described with respect to FIGS. 1 and 3.

While there have been shown and described and noted fundamental novel features of the invention as applied to preferred embodiments thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1. A method of housing a plurality of integrated circuits in a combined electronic, mechanical, and fluidic module, comprising:
providing a substrate for mounting the plurality of integrated circuits thereon, the substrate having a plate with at least one channel to provide a fluid path way;
forming a seal ring on a lower surface of the substrate;
singulating the substrate to a plurality of chips; and
coupling the plurality of chips onto the module using a flip-chip process.

2. The method of claim 1, wherein the flip-chip process is preformed at room temperature.

3. The method of claim 1, wherein the module comprises a preassembled fluidic having a plurality of channels and an electrical interconnect device.

4. The method of claim 3, wherein the electrical interconnect device comprises a combination of Cr/Cu/Ni/Au layers.

5. The method of claim 1, wherein the integrated circuits comprises one of a biosensor, valve, pump, mixer, cooler, and heater.

6. The method of claim 5, wherein the biosensor is provided with immobilized bio-molecule probes.

7. The method of claim 1, wherein the step of providing a seal ring further comprises the step of providing Au bumps on a lower surface of the substrate.

8. The method of claim 7, wherein the seal ring is substantially thicker than the Au bumps.

9. The method of claim 1, wherein the flip-chip process includes an ultrasonic bonding or a laser welding.

10. The method of claim 1, further comprising the step of applying an underfill after coupling the plurality of chips onto the module.

11. The method of claim 1, wherein the seal ring is integrated in a flexible intermediate layer.

12. The method of claim 11, wherein the flexible intermediate layer is coupled to a rigid plastic plate having a plurality of cavities.

13. The method of claim 1, wherein the seal ring is dipped into a thin layer of adhesive prior to the flip-chip process.

14. A package system for housing a plurality of integrated circuits, comprising:
a substrate for mounting the plurality of integrated circuits thereon Again, we want to claim broadly;
a seal ring coupled to the substrate;
a preassembled fluidic having a plurality of channels; and
an electrical interconnect device coupled between the seal ring and the preassembled fluidic

15. The package system of claim 14, wherein the electrical interconnect device comprises a combination of Cr/Cu/Ni/Au layers.

16. The package system of claim 14, wherein the integrated circuits comprises one of a biosensor, valve, pump, mixer, cooler, and heater.

17. The package system of claim 14, further comprises Au bumps on a lower surface of the substrate.

18. The package system of claim 17, wherein the seal ring is substantially thicker than the Au bumps.

19. An apparatus for housing a plurality of integrated circuits, comprising:
a substrate for mounting the plurality of integrated circuits thereon;
a seal ring coupled to the substrate; and
a combined electronic, mechanical, and fluidic module, the module including:
a preassembled fluidic having a plurality of channels; and
an electrical interconnect device coupled between the seal ring and the preassembled fluidic.

20. The apparatus of claim 19, wherein the electrical interconnect device comprises a combination of Cr/Cu/Ni/Au layers.

21. The apparatus of claim 19, wherein the integrated circuits comprises one of a biosensor, valve, pump, mixer, cooler, and heater.

22. The apparatus of claim 19, further comprises Au bumps on a lower surface of the substrate.

23. The apparatus of claim 19, wherein the seal ring is substantially thicker than the Au bumps.
